(19) United States
(12) Patent Application Publication
(10) Pub. No.: US 2025/0280533 A1
(43) Pub. Date: Sep. 4, 2025

(54) SEMICONDUCTOR DEVICE AND METHOD OF FORMING THE SAME

(71) Applicant: NANYA TECHNOLOGY CORPORATION, New Taipei city (TW)

(72) Inventors: Wei Zhong LI, New Taipei City (TW); Hsih-Yang CHIU, New Taipei City (TW)

(21) Appl. No.: 18/593,863

(22) Filed: Mar. 2, 2024

(51) Int. Cl. H10B 20/25

(52) U.S. Cl. CPC H10B 20/25

(57) ABSTRACT

The present disclosure provides a semiconductor device. The semiconductor device includes a substrate, an electronic fuse, and a switching transistor. The electronic fuse is on the substrate. The switching transistor is on the substrate and next to the electronic fuse, in which a first doping region of the substrate underneath the electronic fuse has a first conductive type, a second doping region of the substrate underneath the switching transistor has a second conductive type, the first conductive type and the second conductive type are the same, the first doping region of the substrate is disposed between third doping regions of the substrate, and third conductive types of the third doping regions are different from the first conductive type.

### BACKGROUND

### Field of Invention

The present disclosure relates to a semiconductor device and a method of forming the same.

### Description of Related Art

Electronic fuses are designed as sacrificial components and may be used in semiconductor devices to protect the semiconductor devices from being damaged and/or improve the performance efficiency of the semiconductor devices. For example, the electronic fuse is designed to be blown when too much electric flow is passing through the electronic fuse, thereby protecting the semiconductor from being damaged by a high voltage. In addition, by blowing the electronic fuse(s) in the semiconductor device, a flow path of the current in the semiconductor may change to provide various circuits depending on the requirements. In some situations, when a component fails to work in the semiconductor device, the electronic fuse connected to that component may be blown to avoid slowing down the performance efficiency of the semiconductor devices. However, as the dimension of the semiconductor device shrinks, distances between the electronic fuse and other components also become smaller. When the electronic fuse is packed too close to the nearby component and the types of dopants implanted under the electronic fuse and the nearby component are different, the dopants may diffuse and cause contamination, thereby perishing the function of the electronic fuse and/or the nearby component. Therefore, it is necessary to develop a new semiconductor device including the electronic fuse and a method of forming the same to satisfy every aspect.

### SUMMARY

The present disclosure provides a semiconductor device. The semiconductor device includes a substrate, an electronic fuse, and a switching transistor. The electronic fuse is on the substrate. The switching transistor is on the substrate and next to the electronic fuse, in which a first doping region of the substrate underneath the electronic fuse has a first conductive type, a second doping region of the substrate underneath the switching transistor has a second conductive type, the first conductive type and the second conductive type are the same, the first doping region of the substrate is disposed between third doping regions of the substrate, and third conductive types of the third doping regions are different from the first conductive type.

In some embodiments, the first doping region and the third doping regions are disposed between source/drain doping regions of the substrate.

In some embodiments, depths of the source/drain doping regions in the substrate are larger than depths of the third doping regions in the substrate.

In some embodiments, dopant concentrations of the source/drain doping regions are larger than dopant concentrations of the third doping regions.

In some embodiments, fourth conductive types of the source/drain doping regions are the same as the third conductive types.

In some embodiments, the second doping region of the substrate is disposed between fourth doping regions of the substrate, fourth conductive types of the fourth doping regions are different from the second conductive type, and one of the source/drain doping regions extends continuously from one of the third doping regions to one of the fourth doping regions.

In some embodiments, the first doping region is in direct contact with the third doping regions.

In some embodiments, the electronic fuse includes a gate structure, first spacers on sidewalls of the gate structure, and second spacers on the first spacers.

In some embodiments, the first doping region is disposed below the gate structure and the first spacers, and the third doping regions are disposed below the second spacers.

In some embodiments, the first conductive type is a P type, the second conductive type is a P type, and the third conductive types are N types; or the first conductive type is an N type, the second conductive type is an N type, and the third conductive types are P types.

In some embodiments, a minimum distance between a gate structure of the electronic fuse and a gate structure of the switching transistor is smaller than 100 nm.

The present disclosure also provides a method of forming semiconductor device. The method includes the following operations. A first ion implantation process is performed to form a first implantation region in the substrate. A gate structure of an electronic fuse and a gate structure of a switching transistor are formed on the first implantation region. First spacers are formed on sidewalls of the gate structure of the electronic fuse. A second ion implantation process is performed adjacent to the first spacers to transform first portions of the first implantation region into second implantation regions in the substrate, in which conductive types of the second implantation regions are different from a conductive type of the first implantation region. Second spacers are formed on the first spacers. A third ion implantation process is performed adjacent to the second spacers to transform first portions of the second implantation regions into third implantation regions in the substrate, in which conductive types of the third implantation regions are the same as conductive types of the second implantation regions.

In some embodiments, after performing the third ion implantation process, a second portion of the first implantation region is remained below the gate structure and the first spacers, second portions of the second implantation regions are remained below the second spacers, and the second portion of the first implantation region and the second portions of the second implantation regions are located between the third implantation regions.

In some embodiments, an ion implantation energy used in the third ion implantation process is larger than an ion implantation energy used in the second ion implantation process.

In some embodiments, a dopant concentration used in the second ion implantation process is from 1×10¹³ atoms/cm³ to 1×10¹⁵ atoms/cm³, and a dopant concentration used in the third ion implantation process is from 1×10¹⁴ atoms/cm³ to 1×10¹⁶ atoms/cm³.

In some embodiments, forming the first spacers further includes forming the first spacers on sidewalls of the gate structure of the switching transistor, and after performing the third ion implantation process, second portions of the second implantation regions are remained and located adjacent to the gate structure of the electronic fuse, third portions of the second implantation regions are remained and located adjacent to the gate structure of the switching transistor, and one of the third implantation regions extends continuously from one of the second portions of the second implantation regions to one of the third portions of the second implantation regions.

In some embodiments, a P type dopant is used in the first ion implantation process, and N type dopants are used in the second ion implantation process and the third ion implantation process; or an N type dopant is used in the first ion implantation process, and P type dopants are used in the second ion implantation process and the third ion implantation process.

In some embodiments, a dopant concentration used in the first ion implantation process is from 1×10¹¹ atoms/cm³ to 1×10¹⁴ atoms/cm³.

### BRIEF DESCRIPTION OF THE DRAWINGS

The present disclosure can be more fully understood by reading the following detailed description of the embodiments, with reference made to the accompanying figures as follows.

FIG. 1 is a cross-sectional view diagram of a semiconductor device of the present disclosure according to some embodiments.

FIG. 2 is a top-view diagram of a semiconductor device of the present disclosure according to some embodiments.

FIG. 3 is a flow chart of a method of forming a semiconductor device of the present disclosure according to some embodiments.

FIGS. 4 to 10 are cross-sectional view diagrams of the structures during the formation of a semiconductor device using a method of the present disclosure according to some embodiments.

### DETAILED DESCRIPTION

To make the description of the present disclosure detailed and complete, the following is an illustrative description of the aspects of the embodiments. This is not to limit the embodiments of the present disclosure to only one form. The embodiments of the present disclosure may be combined or substituted with each other when it is beneficial, and other embodiments may be added without further explanation.

In addition, spatially relative terms, such as below and above, etc., may be used in the present disclosure to describe the relationship between one element (or feature) to another element (or feature) in the figures. In addition to the orientation depicted in the figures, spatially relative terms are intended to encompass different orientations of the device in use or in operation. For example, the device may be oriented otherwise (e.g., rotated at 90 degrees), and the spatially relative terms can be interpreted accordingly. In the present disclosure, unless otherwise indicated, the same element numbers in different figures refer to the same or similar elements formed from the same or similar materials by the same or similar methods.

The terms “around”, “approximately”, “nearly”, “basically”, “substantially”, etc., used in the present disclosure include the stated values (or characteristics) and a deviation of the stated values (or characteristics) understood by one skilled in the art. For example, considering the errors of the values (or characteristics), these terms may indicate the values within one or more standard deviations (e.g., the values within ±30%, ±20%, ±15%, ±10%, or ±5%), or may indicate the characteristics including the deviation from the practical operation (e.g., the “substantially parallel” may indicate close to parallel in practical, rather than a perfect ideally parallelism). Furthermore, it is possible to select an acceptable range of the deviation according to the nature of the measurement or other properties, instead of applying only one single deviation range to all the values (or characteristics).

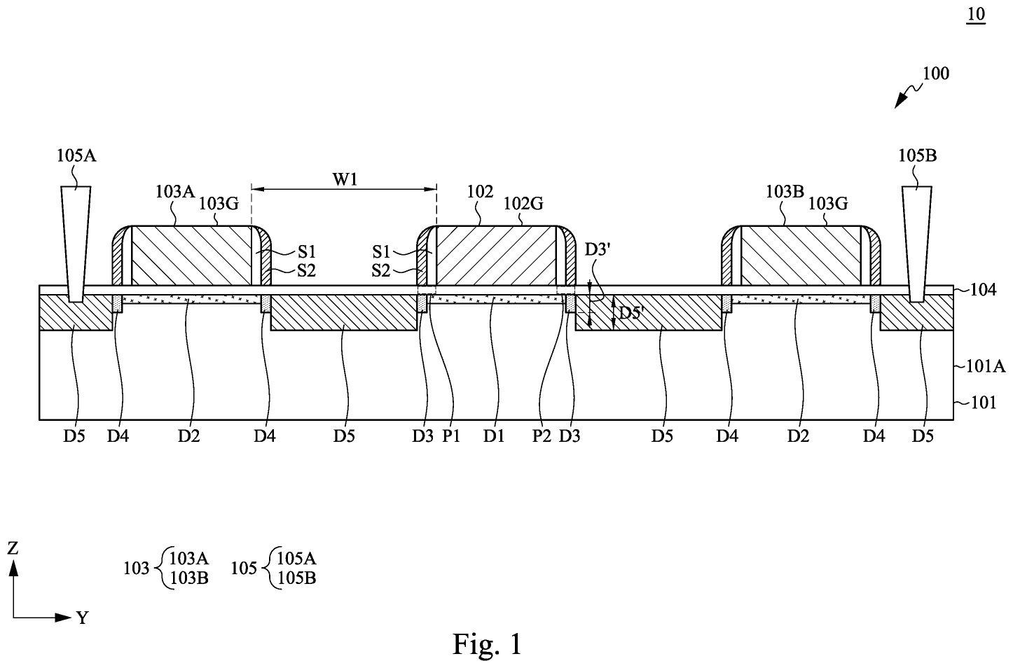

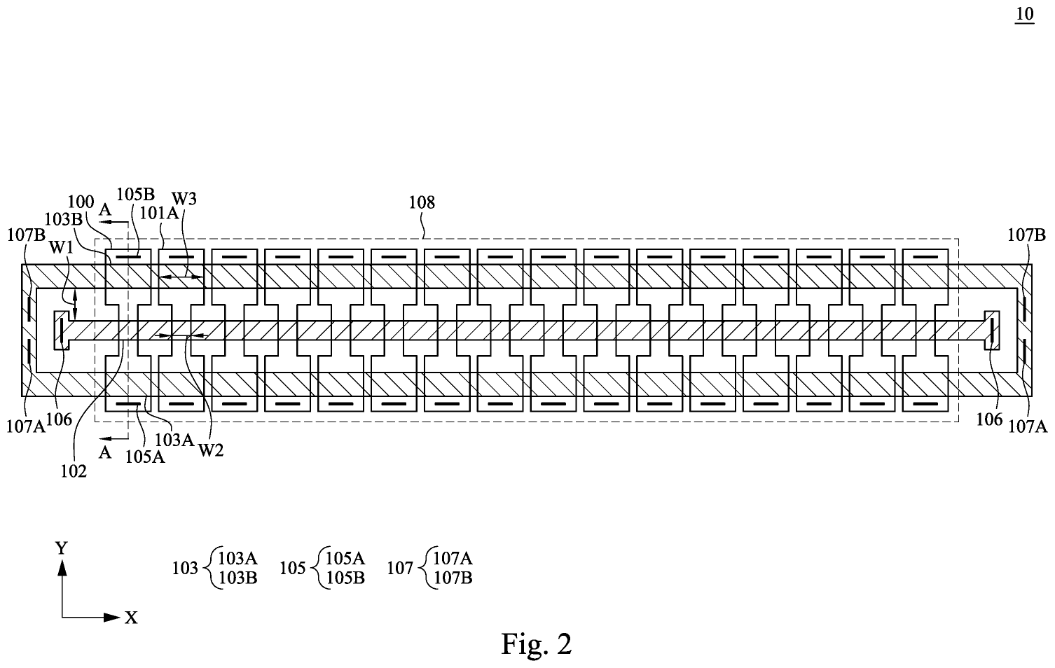

The present disclosure provides a semiconductor device 10, as shown in FIGS. 1 and 2, in which FIG. 1 is a cross-sectional view of FIG. 2 along a line A-A. The semiconductor device 10 includes a substrate 101, an electronic fuse 102, and switching transistors 103. The electronic fuse 102 is disposed on the substrate 101. The switching transistors 103 are disposed on the substrate 101 and next to the electronic fuse 102, in which a first doping region D1 of the substrate 101 underneath the electronic fuse 102 has a first conductive type, a second doping region D2 of the substrate 101 underneath each of the switching transistors 103 has a second conductive type, the first conductive type and the second conductive type are the same, the first doping region D1 of the substrate 101 is disposed between third doping regions D3 of the substrate 101, and third conductive types of the third doping regions D3 are different from the first conductive type. Since the first conductive type of the first doping region D1 and the second conductive type of the second doping region D2 disposed underneath the electronic fuse 102 and the switching transistor 103 are the same, the dopant of the first doping region D1 and the dopant of the second doping region D2 may not be contaminated with each other during the formation of the semiconductor device 10, considering the dopant may diffuse between regions, especially when the distance (e.g., a minimum distance W1 described below) between the electronic fuse 102 and the switching transistor 103 is small (e.g., smaller than 100 nm). The formation of the semiconductor device 10 may also be simplified by forming the first doping region D1 and the second doping region D2 together in a single implantation process (e.g., a first ion implantation process 201 described below). Moreover, when the distance between the electronic fuse 102 and the switching transistor 103 becomes smaller, compared with separately implanting a small area of the first doping region D1 and a small area of the second doping region D2, the single implantation process is much more favorable by implanting a large area (e.g., a dashed line 108 indicated by the embodiment shown in FIG. 2) of the first doping region D1 and the second doping region D2 in the process, considering the manufacturing tool nowadays may not be able to form a small enough area of the doping region. The method 20 of the present disclosure is discussed in detail in the following. In addition, the third doping regions D3 beside the first doping region D1 can enable the current to flow more easily in the first doping region D1 when applying a voltage to a gate structure 102G of the electronic fuse 102. Next, the semiconductor device 10 of the present disclosure is described in detail with the following embodiments.

The substrate 101 may be any suitable substrate. In some embodiments, the substrate 101 may be a semiconductor substrate and may include a semiconductor material including an elemental semiconductor material, for example, carbon, monocrystalline silicon, polycrystalline silicon, amorphous silicon, germanium, tin, sulfur, selenium, tellurium, or the like; a compound semiconductor material, for example, silicon carbide, nitride boron, aluminum nitride, gallium nitride, gallium phosphide, gallium arsenide, indium phosphide, indium arsenide, indium antimonide, zinc oxide, or the like; an alloy semiconductor material, for example, SiGe, AlGaAs, InGaAs, InGaP, AlInAs, GaAsP, AlGaN, InGaN, AlGaInP, or the like; or combinations thereof.

The substrate 101 includes different doping regions. For example, the first doping region D1 is underneath the electronic fuse 102 to provide a channel for the current to flow underneath the electronic fuse 102. For example, the second doping region D2 is underneath the switching transistor 103 to provide a channel for the current to flow underneath the switching transistor 103. For example, the third doping regions D3 beside the first doping region D1 enables the current to flow more easily in the first doping region D1 when applying a voltage to the gate structure 102G of the electronic fuse 102. In some embodiments, the substrate 101 further includes fourth doping regions D4, and the second doping region D2 is disposed between the fourth doping regions D4. In some embodiments, the first doping region D1 and the third doping regions D3 are disposed between source/drain doping regions D5, and the second doping region D2 and the fourth doping regions D4 are also disposed between source/drain doping regions D5.

In some embodiments, the first doping region D1 is disposed underneath the gate structure 102G of the electronic fuse 102 and underneath the first spacers S1 disposed on the gate structure 102G of the electronic fuse 102. In some embodiments, the second doping region D2 is disposed underneath the gate structure 103G of the switching transistor 103 and underneath the first spacers S1 disposed on the gate structure 103G of the switching transistor 103. In some embodiments, the third doping regions D3 are disposed underneath the second spacers S2 disposed on the first spacers S1 that are disposed on the gate structure 102G of the electronic fuse 102. In some embodiments, the fourth doping regions D4 are disposed underneath the second spacers S2 disposed on the first spacers S1 that are disposed on the gate structure 103G of the switching transistor 103. In some embodiments, in a portion of the substrate 101 that is disposed underneath a space or a region between the gate structure 102G of the electronic fuse 102 and the gate structure 103G of the switching transistor 103, one of the source/drain doping regions D5 extends continuously from one of the third doping regions D3 to one of the fourth doping regions D4, such that the one of the source/drain doping regions D5 may be shared by the electronic fuse 102 and the switching transistor 103 nearby. In some embodiments, the first doping region D1 is in direct contact with the third doping regions D3. In some embodiments, the second doping region D2 is in direct contact with the fourth doping regions D4. In some embodiments, depths D5′ (e.g., along a third direction Z that is perpendicular to a first direction X and a second direction Y) of the source/drain doping regions D5 in the substrate 101 are larger than depths D3′ (e.g., along the third direction Z) of the third doping regions D3 in the substrate 101. In some embodiments, a ratio of the depth D5′ of either one of the source/drain doping regions D5 to the depth D3′ of either one of the third doping regions D3 is preferably from 1.5 to 7.5, for example, 1.5, 2.5, 3.5, 4.5, 5.5, 6.5, or 7.5, to have enough doping amounts of the source/drain doping regions D5 and the third doping regions D3, have a clear boundary between the working regions of and the source/drain doping regions D5 and the third doping regions D3, and avoid wasting too many manufacturing resources while not having a significant improvement.

The first doping region D1 has the first conductive type, the second doping region D2 has the second conductive type, the third doping regions D3 have the third conductive types, the fourth doping regions D4 have the fourth conductive types, and the source/drain doping regions D5 have the fifth conductive types. The first conductive type and the second conductive type are the same. The third conductive types, the fourth conductive types, and the fifth conductive types are than same and different from the first conductive type and the second conductive type. In some embodiments, the first doping region D1 and the second doping region D2 may respectively include a P type dopant including boron, gallium, or the like, such that the first conductive type and the second conductive type are P types, and the third doping regions D3, the fourth doping regions D4, and the source/drain doping regions D5 may respectively include an N type dopant including phosphorus, antimony, arsenic, or the like, such that the third conductive types, the fourth conductive types, and the fifth conductive types are N types. In some embodiments, the first doping region D1 and the second doping region D2 may respectively include an N type dopant including phosphorus, antimony, arsenic, or the like, such that the first conductive type and the second conductive type are N types, and the third doping regions D3, the fourth doping regions D4, and the source/drain doping regions D5 may respectively include a P type dopant including boron, gallium, or the like, such that the third conductive types, the fourth conductive types, and the fifth conductive types are P types. In some embodiments, a dopant concentration of either one of the first doping region D1 and the second doping region D2 is preferably from 1×10¹¹ atoms/cm³ to 1×10¹⁴ atoms/cm³, for example, 1×10¹¹ atoms/cm³, 1×10¹² atoms/cm³, 1×10¹³ atoms/cm³, or 1×10¹⁴ atoms/cm³. In some embodiments, dopant concentrations of the source/drain doping regions D5 are larger than dopant concentrations of the third doping regions D3 and dopant concentrations of the fourth doping regions D4. In some embodiments, a dopant concentration of either one of the third doping regions D3 and either one of the fourth doping regions D4 is preferably from 1×10¹³ atoms/cm³ to 1×10¹⁵ atoms/cm³, for example, 1×10¹³ atoms/cm³, 5×10¹³ atoms/cm³, 1×10¹⁴ atoms/cm³, 5×10¹⁴ atoms/cm³, or 1×10¹⁵ atoms/cm³. In some embodiments, a dopant concentration of either one of the source/drain doping regions D5 is preferably from 1×10¹⁴ atoms/cm³ to 1×10¹⁶ atoms/cm³, for example, 1×10¹⁴ atoms/cm³, 5×10¹⁴ atoms/cm³, 1×10¹⁵ atoms/cm³, 5×10¹⁵ atoms/cm³, or 1×10¹⁶ atoms/cm³.

In some embodiments, since the first conductive type of the first doping region D1 and the second conductive type of the second doping region D2 disposed underneath the electronic fuse 102 and the switching transistor 103 are the same, a minimum distance W1 between the gate structure 102G of the electronic fuse 102 and the gate structure 103G of the switching transistor 103 may be reduced without making the dopants in the first doping region D1 and the second doping region D2 contaminant with each other. In some embodiments, the minimum distance W1 is preferably in a range between 10 nm and 100 nm, for example, 20 nm, 30 nm, 40 nm, 50 nm, 60 nm, 70 nm, 80 nm, or 90 nm, to effectively reduce the size of the semiconductor device 10 and to avoid a significant interference between the gate structure 102G of the electronic fuse 102 and the gate structure 103G of the switching transistor 103.

In some embodiments, the gate structure 102G of the electronic fuse 102 is disposed between a source structure (not shown) and a drain structure (not shown), and the source structure and the drain structure are disposed on the source/drain doping regions D5 adjacent to the electronic fuse 102. In some embodiments, the gate structure 103G of the switching transistor 103 is disposed between a source structure (not shown) and a drain structure (not shown), and the source structure and the drain structure are disposed on the source/drain doping regions D5 adjacent to the switching transistor 103.

In some embodiments, an insulating layer 104 is disposed on the substrate 101, between the substrate 101 and the gate structure 102G of the electronic fuse 102, and between the substrate 101 and the gate structure 103G of the switching transistor 103. In some embodiments, the insulating layer 104 includes any suitable material, for example, silicon oxide.

In some embodiments, a first electrode 105 is disposed on the source/drain doping regions D5 and on the side of the switching transistor 103 opposite the side facing the electronic fuse 102. The first electrode 105 can be the electrical ground during blowing out the electronic fuse 102 and be used to measure the electrical resistance when determining whether the electronic fuse 102 is blown out or not. In some embodiments, the first electrode 105 includes any suitable material, for example, a metal.

The electronic fuse 102 may be blown out when a high voltage is applied to the gate structure 102G of the electronic fuse 102. For example, when the high voltage is applied to the gate structure 102G of the electronic fuse 102, a portion P1 and a portion P2 of the insulating layer 104 next to the gate structure 102G of the electronic fuse 102 may respectively have probabilities to be blown out. When the portion P1, the portion P2, or a combination thereof is blown out, an electrical short happens underneath the electronic fuse 102. To confirm whether the electrical short happens underneath the electronic fuse 102 or not, a voltage smaller than the voltage to blow out the electronic fuse 102 and larger than a minimum voltage to overcome the p-n junction underneath the electronic fuse 102 can be applied to the gate structure 102G of the electronic fuse 102, and an electrical resistance can be measured at the first electrode 105. When the measured electrical resistance is small enough, the electrical short is determined to happen underneath the electronic fuse 102.

The switching transistor 103 is configured to open or close the channel underneath the switching transistor 103, thereby controlling whether to perform a blown-out operation to the electronic fuse 102 and whether to measure the electrical resistance underneath the electronic fuse 102. For example, when the channel underneath the switching transistor 103 is opened in the blown-out operation, the current of the high voltage can flow from the channel underneath the electronic fuse 102 to the channel underneath the switching transistor 103 and to the electrical ground, such that the electronic fuse 102 has the probability to be blown out. However, when the channel underneath the switching transistor 103 is closed in the blown-out operation, the current of the high voltage is blocked to flow to the electrical ground, such that the electronic fuse 102 fails to be blown out. For example, when the channel underneath the switching transistor 103 is opened during the measurement of the electrical resistance, the current underneath the electronic fuse 102 can flow to the first electrode 105 and be measured. However, when the channel underneath the switching transistor 103 is closed during the measurement of the electrical resistance, the current underneath the electronic fuse 102 fails to flow to the first electrode 105 and be measured.

In some embodiments, the semiconductor device 10 may include a unit 100 including one electronic fuse 102, two switching transistors 103 (e.g., the switching transistor 103A and the switching transistor 103B), and two first electrodes 105 (e.g., the first electrode 105A and the first electrode 105B), as shown in FIG. 1. Therefore, whether the portion P1 of the insulating layer 104 on the first side (e.g., the left-hand side in FIG. 1) of the electronic fuse 102 is blown out or not may be determined by the switching transistor 103A and the first electrode 105A on the same first side of the electronic fuse 102, whether the portion P2 of the insulating layer 104 on the second side (e.g., the right-hand side in FIG. 1) of the electronic fuse 102 is blown out or not may be determined by the switching transistor 103B and the first electrode 105B on the same second side of the electronic fuse 102, and the first side and the second side are substantially opposite to each other. Since the two switching transistors 103 may work independently by opening or closing each corresponding channel, whether the portion P1 and the portion P2 are blown out or not can be measured independently.

The number of the units 100 is not limited. In some embodiments, the number of the units 100 is preferably an integral in a range from 1 to 20, for example, 1, 4, 8, 12, 16, or 20 (e.g., 16 shown in FIG. 2). In some embodiments, the units 100 are arranged along the first direction X, and the electronic fuse 102, the switching transistors 103, and the first electrodes 105 in each of the units 100 are arranged along the second direction Y perpendicular to the first direction X. In some embodiments, the electronic fuse 102, the switching transistors 103, and the first electrodes 105 in one of the units 100 are respectively aligned with the electronic fuse 102, the switching transistors 103, and the first electrodes 105 in another one of the units 100. In some embodiments, the switching transistor 103A and the switching transistor 103A in the same one of the units 100 are physically connected from the top view, as shown in FIG. 2. In some embodiments, the electronic fuses 102 and the switching transistors 103 in different units 100 are physically connected from the top view, as shown in FIG. 2. In some embodiments, second electrodes 106 may be common electrodes for the electronic fuses 102 that are physically connected, such that a voltage to blow out the electronic fuses 102 and/or a voltage to read the electrical resistance of the electronic fuses 102 may be simultaneously applied to the electronic fuses 102. In some embodiments, the second electrodes 106 disposed on the electronic fuses 102 are arranged along the first direction X and the electronic fuses 102 that are physically connected are disposed between the second electrodes 106. In some embodiments, third electrodes 107 may be common electrodes for the switching transistors 103 that are physically connected, such that the switching transistors 103 in different units 100 may be simultaneously opened and/or closed. In some embodiments, the third electrodes 107 disposed on the switching transistors 103 include third electrodes 107A and third electrodes 107B, in which the switching transistors 103A are disposed between the third electrodes 107A, and the switching transistors 103B are disposed between the third electrodes 107B. It is noted that since each of the units 100 includes the first electrode 105A and the first electrode 105B, the units 100 may work independently, for example, by selectively electrically grounding some first electrodes 105 and/or selectively reading the electrical resistance of some first electrodes 105.

In some embodiments, each of the units 100 is disposed on a corresponding one of the active regions 101A of the substrate 101, and different active regions 101A are separated from each other by an isolation region of the substrate 101. In some embodiments, in each of the units, a width W2 of the active region 101A underneath the electronic fuse 102 is smaller than a width W3 of the active region 101A underneath the switching transistor 103, such that the channel underneath the switching transistor 103 is larger than the channel underneath the electronic fuse 102, and the electronic fuse 102 may be more easily blown out, considering a smaller channel underneath the electronic fuse 102.

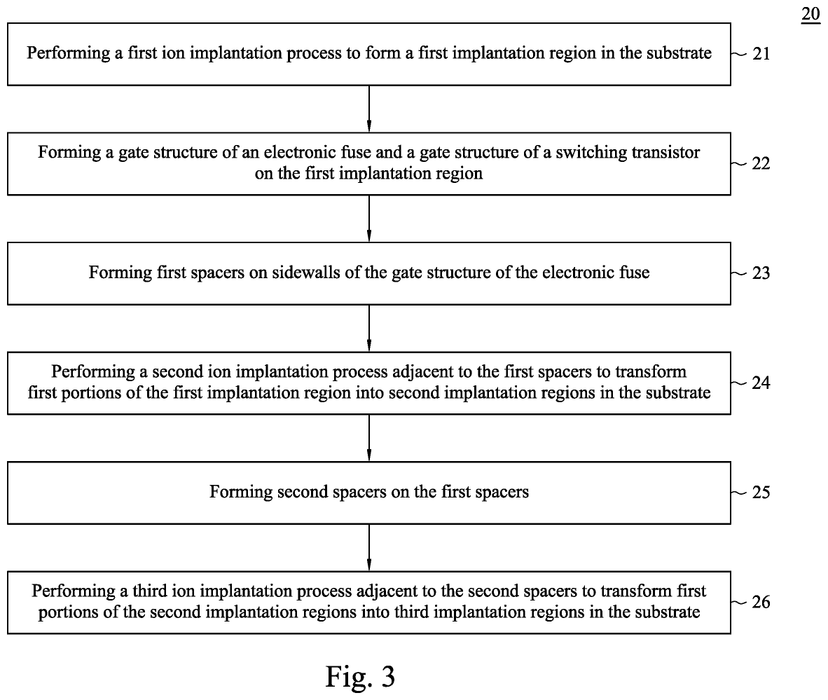

The present disclosure also provides a method 20 of forming the semiconductor device 10 described above. The method 20 shown in the flow chart of FIG. 3 includes an operation 21 to an operation 26. The operation 21 includes performing a first ion implantation process 201 to form a first implantation region 202 in the substrate 101. The operation 22 includes forming the gate structure 102G of the electronic fuse 102 and the gate structure 103G of the switching transistor 103 on the first implantation region 202. The operation 23 includes forming the first spacers S1 on sidewalls of the gate structure 102G of the electronic fuse 102. The operation 24 includes performing a second ion implantation process 206 adjacent to the first spacers S1 to transform first portions 202A of the first implantation region 202 into second implantation regions 207 in the substrate 101, in which conductive types of the second implantation regions 207 are different from a conductive type of the first implantation region 202. The operation 25 includes forming the second spacers S2 on the first spacers S1. The operation 26 includes performing a third ion implantation process 209 adjacent to the second spacers S2 to transform first portions 207A of the second implantation regions 207 into third implantation regions (i.e., the source/drain doping regions D5 described above) in the substrate 101, in which conductive types of the third implantation regions are the same as conductive types of the second implantation regions 207. Next, the method 20 of the present disclosure is described in detail with the following embodiments.

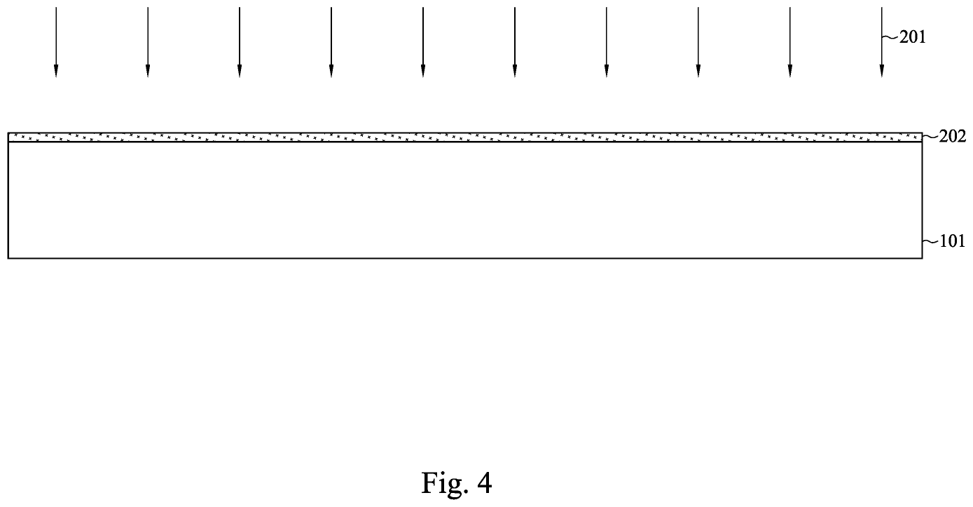

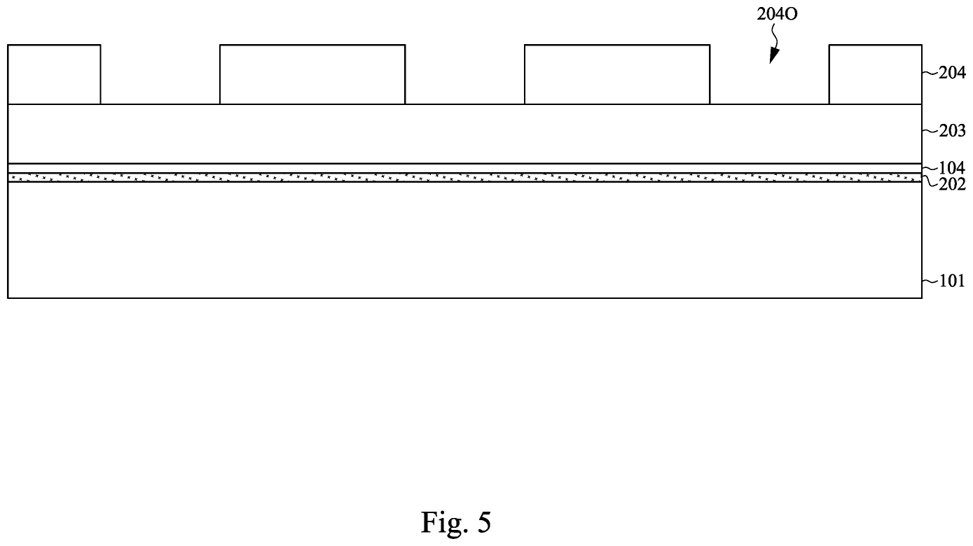

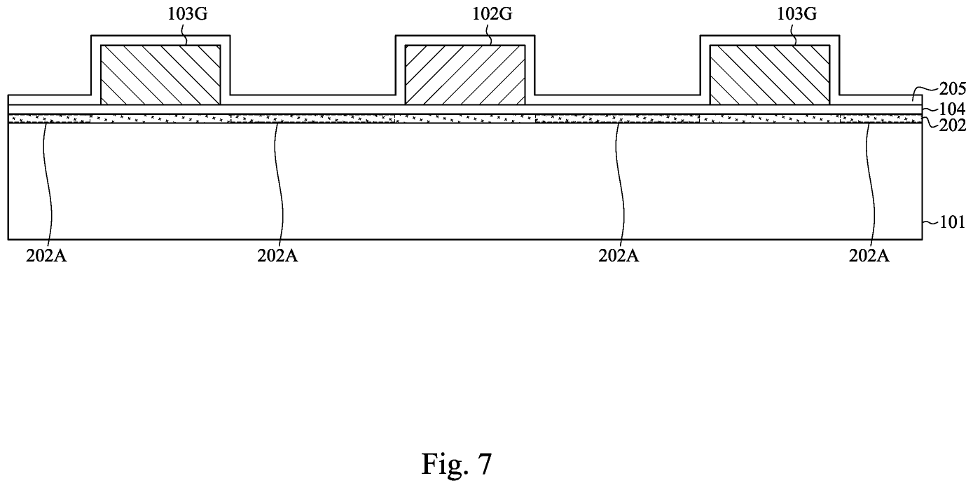

The operation 21 includes performing the first ion implantation process 201 to form the first implantation region 202 in the substrate 101, as shown in FIG. 4. Portions (e.g., the first potions 202A in FIG. 7) of the first implantation region 202 will be transformed to the second implantation regions 207, and portions of the first implantation region 202 remained underneath the gate structure 102G of the electronic fuse 102, the gate structure 103G of the switching transistor 103, and the first spacers S1 are the first doping region D1 and the second doping region D2 described above. Since the first doping region D1 and the second doping region D2 are implanted together in the first ion implantation process 201, the implantation area (e.g., a dashed line 108 indicated by the embodiment shown in FIG. 2) performed by the first ion implantation process 201 can be larger than the implantation areas performed by separately implanting the first doping region D1 and the second doping region D2. Therefore, the manufacturing tools of forming the separated implantation areas of the first doping region D1 and the second doping region D2 are not required in the present disclosure to avoid reaching the limitation of the manufacturing tools. For example, the pattern formed by the lithography tool may reach a size limitation and cannot be smaller, such that the size of the implantation area based on the pattern formed by the lithography tool is limited. In addition, since the first doping region D1 and the second doping region D2 are implanted together in the first ion implantation process 201, the conductive type of the first doping region D1 and the conductive type of the second doping region D2 are the same. In some embodiments, the P type dopant (e.g., boron, gallium, or the like) is used in the first ion implantation process 201. In some embodiments, the N type dopant (e.g., phosphorus, antimony, arsenic, or the like) is used in the first ion implantation process 201. In some embodiments, a dopant concentration used in the first ion implantation process 201 is preferably from 1×10¹¹ atoms/cm³ to 1×10¹⁴ atoms/cm³, for example, 1×10¹¹ atoms/cm³, 1×10¹² atoms/cm³, 1×10¹³ atoms/cm³, or 1×10¹⁴ atoms/cm³. In some embodiments, as shown in FIG. 5, after forming the first implantation region 202, the insulating layer 104 is formed on the first implantation region 202 by any suitable deposition method, for example, a chemical deposition process or a physical deposition process.

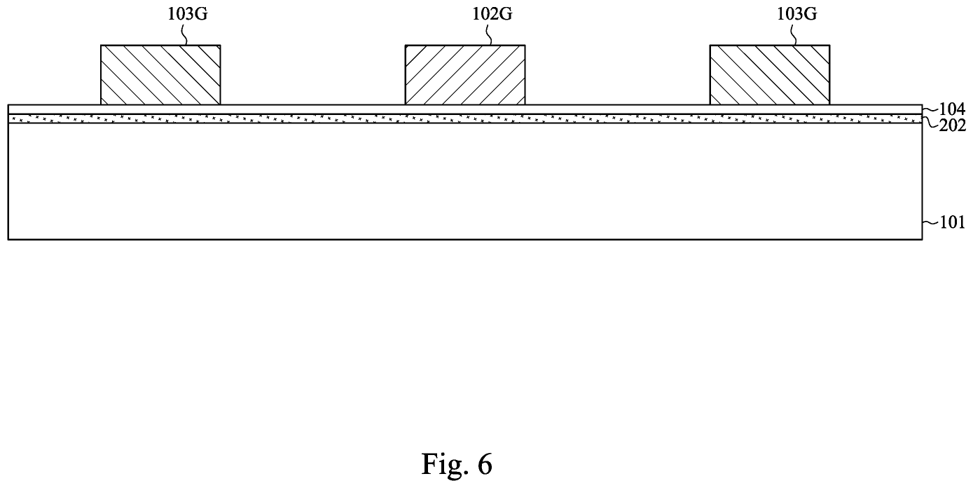

The operation 22 includes forming the gate structure 102G of the electronic fuse 102 and the gate structure 103G of the switching transistor 103 on the first implantation region 202, as shown in FIGS. 5 to 6. In some embodiments, a material 203 of the gate structure 102G and the gate structure 103G is formed on the first implantation region 202 by any suitable deposition method, for example, a chemical deposition process or a physical deposition process. Next, a patterned photoresist layer 204 is formed on the material 203 to define the pattern of the gate structure 102G and the gate structure 103G. Specifically, portions of the material 203 exposed by openings 2040 of the patterned photoresist layer 204 are removed by any suitable etching method, for example, a dry etching process or a wet etching process, to form the gate structure 102G and the gate structure 103G. In some embodiments, after forming the gate structure 102G and the gate structure 103G, the photoresist layer 204 is removed.

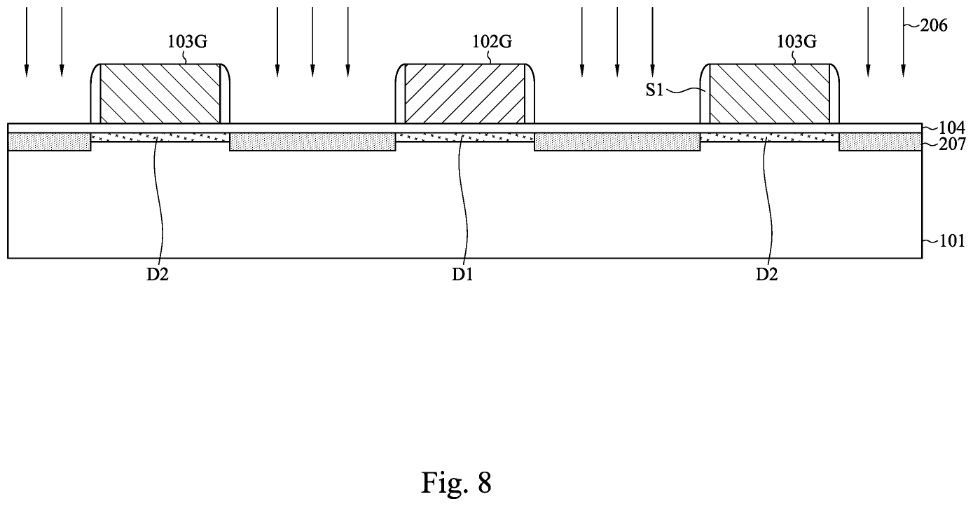

The operation 23 includes forming the first spacers S1 on sidewalls of the gate structure 102G of the electronic fuse 102, as shown in FIGS. 7 to 8. In some embodiments, forming the first spacers S1 further includes forming the first spacers S1 on sidewalls of the gate structure 103G of the switching transistor 103. Specifically, a material 205 of the first spacers S1 is conformally formed on the gate structure 102G and the gate structure 103G by any suitable deposition method, for example, an atomic layer deposition process. Next, portions of the material 205 are removed by any suitable etching method, for example, a dry etching process or a wet etching process, to remain portions of the material 205 on the sidewalls of the gate structure 102G and the sidewalls of the gate structure 103G. In some embodiments, the material 205 may be any suitable material, for example, silicon nitride. The first spacers S1 will be used to define the position of the second implantation regions 207 in the following operation and portions of the substrate 101 underneath the first spacers S1 can be used to provide tolerance for the diffusion of the second implantation regions 207.

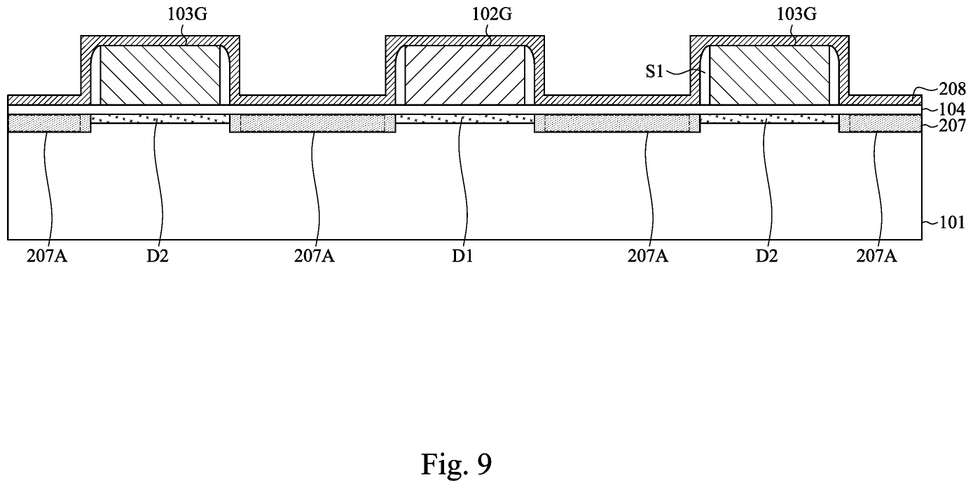

The operation 24 includes performing the second ion implantation process 206 adjacent to the first spacers S1 to transform the first portions 202A of the first implantation region 202 into the second implantation regions 207 in the substrate 101, as shown in FIGS. 7 to 8, in which conductive types of the second implantation regions 207 are different from a conductive type of the first implantation region 202. Portions (e.g., the first potions 207A in FIG. 9) of the second implantation regions 207 will be transformed to the third implantation regions (i.e., the source/drain doping regions D5), and portions of the second implantation regions 207 remained underneath the second spacers S2 are the third doping regions D3 and the fourth doping regions D4 described above. In the embodiments that the P type dopant is implanted in the first implantation region 202, the N type dopant (e.g., phosphorus, antimony, arsenic, or the like) is used in the second ion implantation process 206. In the embodiments that the N type dopant is implanted in the first implantation region 202, the P type dopant (e.g., boron, gallium, or the like) is used in the second ion implantation process 206. In some embodiments, a dopant concentration used in the second ion implantation process 206 is preferably from 1×10¹³ atoms/cm³ to 1×10¹⁵ atoms/cm³, for example, 1×10¹³ atoms/cm³, 5×10¹³ atoms/cm³, 1×10¹⁴ atoms/cm³, 5×10¹⁴ atoms/cm³, or 1×10¹⁵ atoms/cm³. In some embodiments, an ion implantation energy used in the second ion implantation process 206 is preferably from 2 KeV to 10 KeV, for example, 2 KeV, 4 KeV, 6 KeV, 8 KeV, or 10 KeV, such that a desirable depth (e.g., the depths D3′ described above) of the second implantation regions 207 can be achieved.

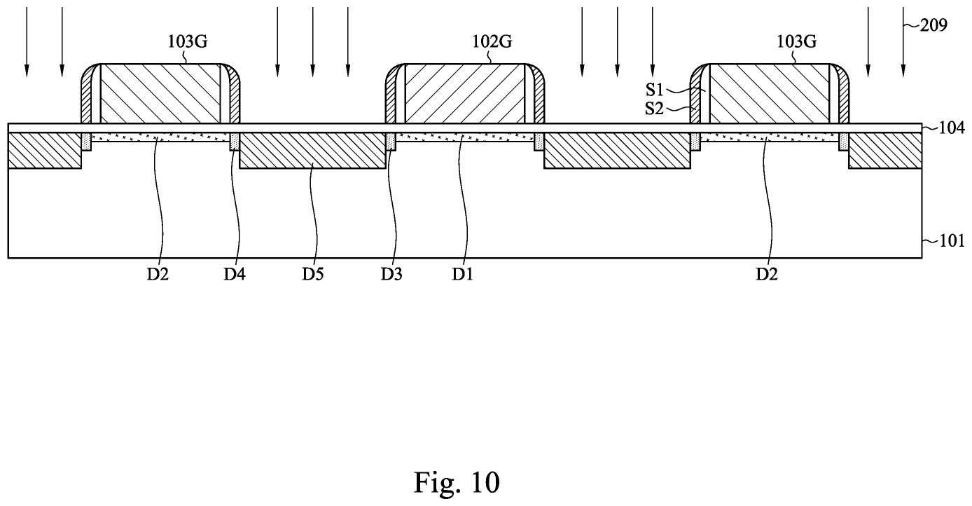

The operation 25 includes forming the second spacers S2 on the first spacers S1, as shown in FIGS. 9 to 10. Specifically, a material 208 of the second spacers S2 is conformally formed on the first spacers S1, the gate structure 102G and the gate structure 103G by any suitable deposition method, for example, an atomic layer deposition process. Next, portions of the material 208 are removed by any suitable etching method, for example, a dry etching process or a wet etching process, to remain portions of the material 208 on the first spacers S1. In some embodiments, the material 208 may be any suitable material, for example, silicon nitride. The second spacers S2 will be used to define the position of the third implantation regions (i.e., the source/drain doping regions D5) in the following operation and portions of the substrate 101 underneath the second spacers S2 can be used to provide tolerance for the diffusion of the third implantation regions.

The operation 26 includes performing the third ion implantation process 209 adjacent to the second spacers S2 to transform the first portions 207A of the second implantation regions 207 into the third implantation regions (i.e., the source/drain doping regions D5) in the substrate 101, as shown in FIG. 10, in which conductive types of the third implantation regions are the same as conductive types of the second implantation regions 207. After performing the third ion implantation process 209, portions of the first implantation region 202 remained underneath the gate structure 102G and the gate structure 103G are respectively the first doping regions D1 and the second doping regions D2 described above, portions of the second implantation regions 207 remained underneath the second spacers S2 are the third doping regions D3 and the fourth doping regions D4 described above, and the third implantation regions are the source/drain doping regions D5 described above. In the embodiments that the P type dopant is implanted in the first implantation region 202, the N type dopants (e.g., phosphorus, antimony, arsenic, or the like) are used in the second ion implantation process 206 and the third ion implantation process 209. In the embodiments that the N type dopant is implanted in the first implantation region 202, the P type dopants (e.g., boron, gallium, or the like) are used in the second ion implantation process 206 and the third ion implantation process 209. In some embodiments, a dopant concentration used in the third ion implantation process 209 is preferably from 1×10¹⁴ atoms/cm³ to 1×10¹⁶ atoms/cm³, for example, 1×10¹⁴ atoms/cm³, 5×10¹⁴ atoms/cm³, 1×10¹⁵ atoms/cm³, 5×10¹⁵ atoms/cm³, or 1×10¹⁶ atoms/cm³. In some embodiments, an ion implantation energy used in the third ion implantation process 209 is larger than the ion implantation energy used in the second ion implantation process 206. In some embodiments, the ion implantation energy used in the third ion implantation process 209 is preferably from 10 KeV to 15 KeV, for example, 10 KeV, 11 KeV, 12 KeV, 13 KeV, 14 KeV, or 15 KeV, such that a desirable depth (e.g., the depths D5′ described above) of the third implantation regions can be achieved. In some embodiments, after performing the third ion implantation process 209, the first electrodes 105 is formed on the third implantation regions to obtain the semiconductor device 10 shown in FIG. 1.

In some embodiments, when a plurality of units 100 described above is formed, the first implantation region 202 formed in the operation 21 extends between different units 100 as a region indicated by the dashed line 108 shown in FIG. 2. In addition, the material 203 of the gate structure 102G and the gate structure 103G formed in the operation 22 extends along the first direction X and the second direction Y, and after patterning the material 203 by the patterned photoresist layer 204, the remained material 203 is shown in FIG. 2, in which the gate structures 102G of the electronic fuses 102 in different units 100 are physically connected, and the gate structures 103G of the switching transistors 103 in different units 100 are physically connected. In addition, the second electrodes 106 are formed on portions of the remained material 203 physically connected to the gate structures 102G, and the third electrodes 107 are formed on portions of the remained material 203 physically connected to the gate structures 103G.

The semiconductor device and the method of forming the same avoid the diffusion of the dopants to contaminate the doping regions respectively underneath the electronic fuse and the switching transistor. In addition, the size of the semiconductor device can be smaller without having the dopants contaminate the doping regions underneath the electronic fuse and the switching transistor. In addition, the method is much easier and does not exceed the limitations of manufacturing tools nowadays.

The present disclosure is described in considerable detail in some embodiments, but other embodiments may also be feasible, so the description of the embodiments in the present disclosure is not intended to limit the scope and spirit of the claims attached. For one skilled in the art, the present disclosure may be modified and changed without deviating from the scope and spirit of the present disclosure. Such modifications and changes are intended to be covered by the present disclosure when they belong to the scope and spirit of the attached claims.

What is claimed is:

1. A semiconductor device, comprising:
a substrate;
an electronic fuse on the substrate; and
a switching transistor on the substrate and next to the electronic fuse, wherein:
a first doping region of the substrate underneath the electronic fuse has a first conductive type, a second doping region of the substrate underneath the switching transistor has a second conductive type, and the first conductive type and the second conductive type are the same, and;
the first doping region of the substrate is disposed between third doping regions of the substrate, and third conductive types of the third doping regions are different from the first conductive type.

2. The semiconductor device of claim 1, wherein the first doping region and the third doping regions are disposed between source/drain doping regions of the substrate.

3. The semiconductor device of claim 2, wherein depths of the source/drain doping regions in the substrate are larger than depths of the third doping regions in the substrate.

4. The semiconductor device of claim 2, wherein dopant concentrations of the source/drain doping regions are larger than dopant concentrations of the third doping regions.

5. The semiconductor device of claim 2, wherein fourth conductive types of the source/drain doping regions are the same as the third conductive types.

6. The semiconductor device of claim 2, wherein the second doping region of the substrate is disposed between fourth doping regions of the substrate, fourth conductive types of the fourth doping regions are different from the second conductive type, and one of the source/drain doping regions extends continuously from one of the third doping regions to one of the fourth doping regions.

7. The semiconductor device of claim 1, wherein the first doping region is in direct contact with the third doping regions.

8. The semiconductor device of claim 1, wherein the electronic fuse comprises a gate structure, first spacers on sidewalls of the gate structure, and second spacers on the first spacers.

9. The semiconductor device of claim 8, wherein the first doping region is disposed below the gate structure and the first spacers, and the third doping regions are disposed below the second spacers.

10. The semiconductor device of claim 1, wherein:
the first conductive type is a P type, the second conductive type is a P type, and the third conductive types are N types; or
the first conductive type is an N type, the second conductive type is an N type, and the third conductive types are P types.

11. The semiconductor device of claim 1, wherein a minimum distance between a gate structure of the electronic fuse and a gate structure of the switching transistor is smaller than 100 nm.

12. A method of forming semiconductor device, comprising:
performing a first ion implantation process to form a first implantation region in a substrate;
forming a gate structure of an electronic fuse and a gate structure of a switching transistor on the first implantation region;
forming first spacers on sidewalls of the gate structure of the electronic fuse;
performing a second ion implantation process adjacent to the first spacers to transform first portions of the first implantation region into second implantation regions in the substrate, wherein conductive types of the second implantation regions are different from a conductive type of the first implantation region;
forming second spacers on the first spacers; and
performing a third ion implantation process adjacent to the second spacers to transform first portions of the second implantation regions into third implantation regions in the substrate, wherein conductive types of the third implantation regions are the same as conductive types of the second implantation regions.

13. The method of claim 12, wherein after performing the third ion implantation process, a second portion of the first implantation region is remained below the gate structure and the first spacers, second portions of the second implantation regions are remained below the second spacers, and the second portion of the first implantation region and the second portions of the second implantation regions are located between the third implantation regions.

14. The method of claim 12, wherein an ion implantation energy used in the third ion implantation process is larger than an ion implantation energy used in the second ion implantation process.

15. The method of claim 12, wherein a dopant concentration used in the second ion implantation process is from 1×10¹³ atoms/cm³ to 1×10¹⁵ atoms/cm³, and a dopant concentration used in the third ion implantation process is from 1×10¹⁴ atoms/cm³ to 1×10¹⁶ atoms/cm³.

16. The method of claim 12, wherein:
forming the first spacers further comprises forming the first spacers on sidewalls of the gate structure of the switching transistor; and
after performing the third ion implantation process, second portions of the second implantation regions are remained and located adjacent to the gate structure of the electronic fuse, third portions of the second implantation regions are remained and located adjacent to the gate structure of the switching transistor, and one of the third implantation regions extends continuously from one of the second portions of the second implantation regions to one of the third portions of the second implantation regions.

17. The method of claim 12, wherein:
a P type dopant is used in the first ion implantation process, and N type dopants are used in the second ion implantation process and the third ion implantation process; or
an N type dopant is used in the first ion implantation process, and P type dopants are used in the second ion implantation process and the third ion implantation process.

18. The method of claim 12, wherein a dopant concentration used in the first ion implantation process is from 1×10¹¹ atoms/cm³ to 1×10¹⁴ atoms/cm³.
